(19) United States
(12) Patent Application Publication
(10) Pub. No.: US 2013/0181771 A1
(43) Pub. Date: Jul. 18, 2013

(54) LIGHT RECEIVING CIRCUIT AND PHOTO-COUPLING TYPE INSULATED CIRCUIT

(71) Applicant: Yukio TSUNETSUGU, Fukuoka-ken (JP)

(72) Inventor: Yukio TSUNETSUGU, Fukuoka-ken (JP)

(73) Assignee: Kabushiki Kaisha Toshiba, Tokyo (JP)

(21) Appl. No.: 13/595,699

(22) Filed: Aug. 27, 2012

(30) Foreign Application Priority Data
Jan. 17, 2012 (JP) 2012-007487

(51) Int. Cl. H03F 3/45

(52) U.S. Cl. 330/69

(57) ABSTRACT

According to one embodiment, a light receiving circuit includes a light receiving element, an amplifier, and a first compensator. The light receiving element is configured to output an optical current by receiving an optical signal. The amplifier is configured to convert the optical current into a voltage and amplify the voltage. The first compensator is connected to the amplifier and configured to suppress a variation in an opposite direction from a voltage variation of the amplifier when the optical current increases.

### CROSS-REFERENCE TO RELATED APPLICATIONS

This application is based upon and claims the benefit of priority from the prior Japanese Patent Application No. 2012-007487, filed on Jan. 17, 2012; the entire contents of which are incorporated herein by reference.

### FIELD

Embodiments described herein relate generally to a light receiving circuit and a photo-coupling type insulated circuit.

### BACKGROUND

In an environment where high-power electrical equipment and highly-sensitive electronic equipment such as an electric vehicle or FA equipment coexist, an insulated circuit having large noise tolerance, for example, an insulative amplifier is used. For example, in a photo-coupling type insulated circuit optically transmitting a signal, such as a photo coupler or the like, since an input and an output are electrically insulated from each other, the noise tolerance is excellent. In the photo-coupling type insulated circuit, noise current flows on a light receiving circuit at the output side through a small amount of parasitic capacitance between the input and the output, and an incorrect operation caused due to saturation of the light receiving circuit may be suppressed.

### BRIEF DESCRIPTION OF THE DRAWINGS

FIG. 1 is a block diagram illustrating a photo-coupling type insulated circuit including a light receiving circuit according to a first embodiment;

FIG. 2 is an equivalent circuit diagram of a simulation model of a common-mode noise;

FIG. 3 is a block diagram illustrating a photo-coupling type insulated circuit including a light receiving circuit according to a second embodiment;

FIG. 4 is a circuit diagram illustrating a light receiving circuit according to the second embodiment;

FIGS. 5A to 5G are waveform diagrams of signals of the light receiving circuit according to the second embodiment;

FIG. 6 is a circuit diagram of a light receiving circuit of a comparative example;

FIGS. 7A to 7G are waveform diagrams of signals of the comparative example;

FIG. 8 is a block diagram illustrating a photo-coupling type insulated circuit including a light receiving circuit according to a third embodiment;

FIG. 9 is a block diagram illustrating a photo-coupling type insulated circuit including a light receiving circuit according to a fourth embodiment;

FIG. 10 is a circuit diagram illustrating a light receiving circuit according to the fourth embodiment;

FIGS. 11A to 11F are waveform diagrams of signals of the light receiving circuit according to the fourth embodiment;

FIG. 12 is another circuit diagram illustrating a light receiving circuit according to the fourth embodiment;

FIG. 13 is anther circuit diagram illustrating a light receiving circuit according to the fourth embodiment; and

FIG. 14 is a block diagram illustrating a photo-coupling type insulated circuit including a light receiving circuit according to a fifth embodiment.

### DETAILED DESCRIPTION

In general, according to one embodiment, a light receiving circuit includes a light receiving element, an amplifier, and a first compensator. The light receiving element is configured to output an optical current by receiving an optical signal. The amplifier is configured to convert the optical current into a voltage and amplify the voltage. The first compensator is connected to the amplifier and configured to suppress a variation in an opposite direction from a voltage variation of the amplifier when the optical current increases.

According to another embodiment, a photo-coupling type insulated circuit includes a light receiving circuit described above and a light emitting element transmitting an optical signal to the light receiving element.

Hereinafter, embodiments will be described in detail with reference to the accompanying drawings. Further, in the specification and each drawing, the same reference numerals refer to the same components as those described in the previous drawings, and a detailed description thereof will not be repeated. In addition, a logic value, false (“0”) is represented by L and a logic value, true (“1”) is represented by H.

First, a first embodiment will be described.

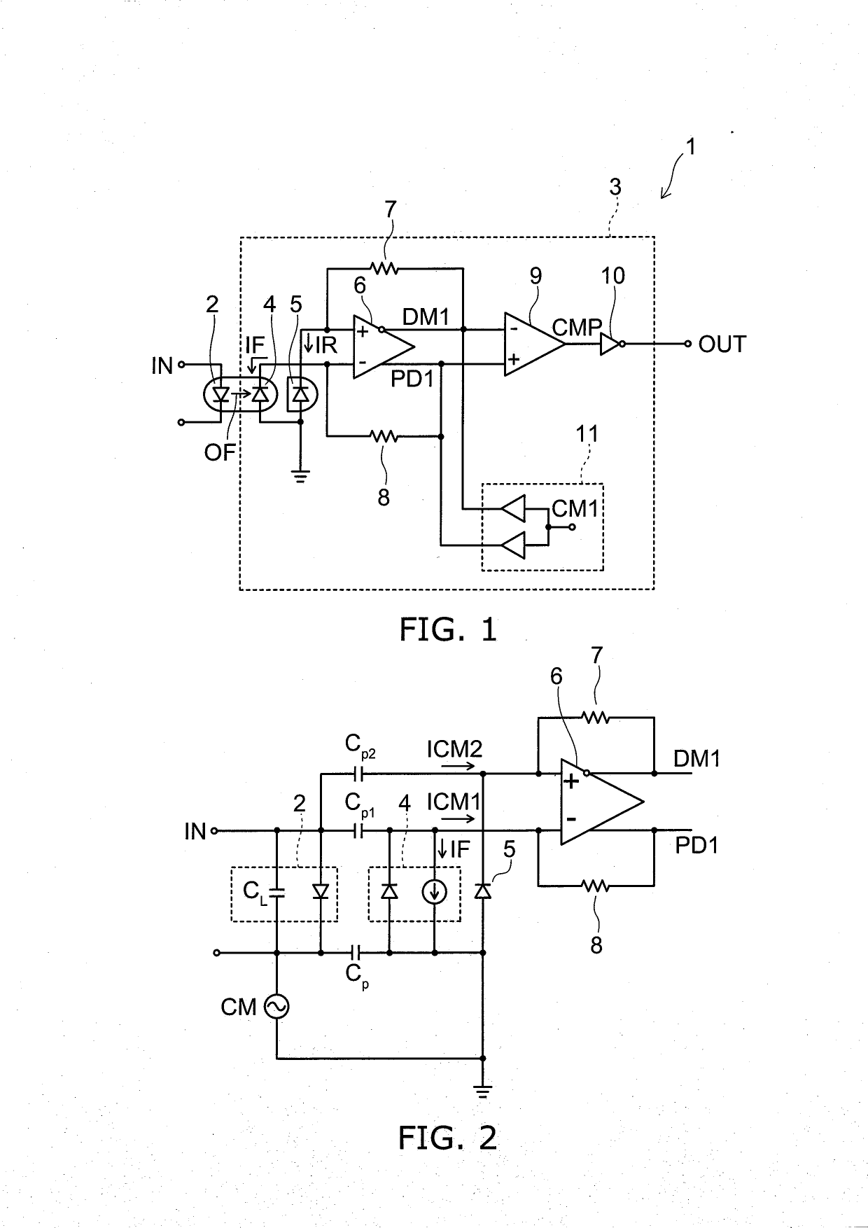

FIG. 1 is a block diagram illustrating a photo-coupling type insulated circuit including a light receiving circuit according to a first embodiment.

As illustrated in FIG. 1, a photo-coupling type insulated circuit 1 includes a light emitting element 2 and a light receiving circuit 3.

The light emitting element 2 is for example, a light emitting diode (LED). The light emitting element 2 converts an input signal IN into an optical signal OF and transmits the corresponding optical signal OF.

The light receiving circuit 3 includes a light receiving element 4 receiving the optical signal OF, a reference element 5 in which the optical signal OF is shielded, an amplifier 6 that converts optical current IF of the light receiving element 4 and reference current IR of the reference element 5 into voltages, respectively to amplify the voltages, feedback resistors 7 and 8, a comparator 9 that compares a pair of voltages output from the amplifier 6, a waveform shaper 10 connected to an output of the comparator 9, and a first compensator 11 connected to the amplifier 6. The light receiving circuit 3 receives the optical signal OF and converts the received optical signal OF into an electric signal, which is output.

The light receiving element 4 is for example photodiode and is connected between one input terminal (−terminal) and an output-side ground of the amplifier 6. The light receiving element 4 is photo-coupled with the light emitting element 2 and converts the received optical signal OF into the optical current IF, which is output.

The reference element 5 is for example, the photodiode and has a pairing property having electric characteristics with the light receiving element 4. The reference element 5 is connected between the other input terminal (+terminal) and the output-side ground of the amplifier 6. The reference element 5 outputs current in the case where the optical signal OF is shielded and the optical signal OF is not received as the reference current IR.

The amplifier 6 is a differential amplifier, and has a pair of input terminals (−terminal and +terminal) and a pair of output terminals. The amplifier 6 converts the optical current IF output from the light receiving element 4 and the reference current IR output from the reference element 5 into voltages, respectively, which are amplified. A voltage PD1 into which the optical current IF is converted and a voltage DM1 into which the reference current IR is converted are output to the pair of output terminals of the amplifier 6.

When the optical current IF which flows toward the light receiving element 4 from one input terminal of the amplifier 6 increases, the voltage PD1 of the amplifier 6 increases. When the reference current IR which flows toward the reference element 5 from the other input terminal of the amplifier 6 increases, the voltage DM1 increases. In the amplifier 6, each of the optical current IF and the reference current IR may be converted into the voltages, respectively, and a configuration thereof is arbitrary. An offset may be provided between the pair of voltages PD1 and DM1 of the amplifier 6 in an unsignalized state, such that a magnitude relationship between the voltages PD1 and DM1 may be prevented from being changed by a manufacturing disparity. Herein, the unsignalized state indicates a state in which the optical signal OF is not received and the electric signal with common-mode noise is not input.

The feedback resistors 7 and 8 are connected between the pair of input terminals and the pair of output terminals of the amplifier 6, respectively. That is, the feedback resistor 7 is connected between the other input terminal of the amplifier 6 connected with the reference element 5 and one output terminal that outputs the voltage DM1. The feedback resistor 8 is connected between one input terminal of the amplifier 6 connected with the light receiving element 4 and the other output terminal that outputs the voltage PD1. The amplifier 6 and the feedback resistors 7 and 8 constitute a trans-impedance amplifier.

The comparator 9 amplifies each of the voltage PD1 and the voltage DM1 and further, compares the voltages PD1 and DM1, which are output as digital signals. The comparator 9 outputs H when the voltage PD1 is higher than the voltage DM1 and outputs L when the voltage PD1 is lower than the voltage DM1.

The waveform shaper 10 is for example, an inverter. The waveform shaper 10 shapes a waveform by speeding up a rising time and a dropping time of an output signal CMP of the comparator 9. An output signal of the waveform shaper 10 is output as output signals OUT of the light receiving circuit 3 and the photo-coupling type insulated circuit 1. The comparator 9 and the waveform shaper 10 may not be provided, and the voltages PD1 and DM1 output from the amplifier 6 may be the output signals of the light receiving circuit 3 and the photo-coupling type insulated circuit 1.

The first compensator 11 is connected to a pair of output terminals of the amplifier 6, and suppresses voltage variation in an opposite direction to a direction in which the voltage PD1 of the amplifier 6 varies when the optical current IF increases. As described above, when the optical current IF increases, the voltage PD1 of the amplifier 6 rises. Therefore, the first compensator 11 suppresses voltage variation in a direction in which the pair of voltages PD1 and DM1 of the amplifier 6 is lower than a voltage value in the unsignalized state.

The first compensator 11 for example, suppresses the drop of the voltages PD1 and DM1 by supplying current to the output terminal when the pair of voltages PD1 and DM1 of the amplifier 6 are lower than the voltage value in the unsignalized state. Further, the first compensator 11 is biased so that a small amount of current (for example, approximately 1 μA) flows even in the unsignalized state. In addition, the first compensator 11 is for example, a clamp circuit, and clamps the pair of voltages PD1 and DM1 to a predetermined value CM1 or more, which is lower than the voltage value in the unsignalized state. Herein, the predetermined value CM1 is a value within a range of the voltages PD1 and DM1 in which the amplifier 6 is not saturated but operable, for example, an operable minimum value.

Next, an operation of the photo-coupling type insulated circuit 1 will be described.

As described above, when the input signal IN is input into the light emitting element 2, the light emitting element 2 transmits the optical signal OF. The light receiving element 4 that receives the optical signal OF outputs the optical current IF. The reference element 5 in which the optical signal OF is shielded outputs the reference current IR. The trans-impedance amplifier constituted by the amplifier 6 and the feedback resistors 7 and 8 converts the optical current IF into the voltage PD1, which is output, and converts the reference current IR into the voltage DM1, which is output. The pair of voltages PD1 and DM1 output from the amplifier 6 is output as the output signal OUT of a digital signal through the comparator 9 and the waveform shaper 10.

Further, when the common-mode noise is applied, noise current flows on the light receiving circuit 3 through the pair of input terminals of the amplifier 6 having largest impedance in the amplifier 6.

FIG. 2 is an equivalent circuit diagram of a simulation model of a common-mode noise.

FIG. 2 illustrates an equivalent circuit of an input part of the light receiving circuit 3 disclosed when the common-mode noise CM is applied between an input-side ground and an output-side ground of the photo-coupling type insulated circuit 1, that is, between a cathode of the light emitting element 2 and an anode of the light receiving element 4 of the light receiving circuit 3. Further, the comparator 9, the waveform shaper 10, and the first compensator 11 will not be described. In addition, the optical current IF of the light receiving element 4 is represented as a constant current source, and the reference current IR of the reference element 5 will not be illustrated.

In the photo-coupling type insulated circuit 1, a space between the light receiving element 4 and the amplifier 6 and a space between the reference element 5 and the amplifier 6 are covered with for example, a conductor having a ground potential and mounted in a shielded layout. However, it is difficult to completely shield the spaces, and a space between the light emitting element 2 and one input terminal at the light receiving element 4 side of the amplifier 6 and a space between the light emitting element 2 and the other input terminal at the reference element 5 side of the amplifier 6 are electrically connected to each other through parasitic capacitances C_{P1} and C_{P2}, respectively. As a result, when a common-mode noise CM is applied, differential noise is input into the pair of input terminals of the amplifier 6 through the parasitic capacitances C_{P1} and C_{P2}.

Capacitance of the light emitting element 2 is represented by C_{L}. The parasitic capacitance between the input-side ground and the output-side ground, that is, the parasitic capacitance between the cathode of the light emitting element 2 and the anode of the light receiving element 4 is represented by C_{P}. The parasitic capacitances C_{P1} and C_{P2} are smaller than the capacitance C_{L} of the light emitting element 2.

When the common-mode noise CM of a common mode voltage VCM is applied, noise currents ICM1 and ICM2 acquired by differentiating the common mode voltage VCM flow on the pair of input terminals of the amplifier 6 through the parasitic capacitance C_{L} of the light emitting element 2, the parasitic capacitance C_{P1} at the light receiving element 4 side, and the parasitic capacitance C_{P2} at the reference element 5 side, respectively. Since the capacitance C_{L} is sufficiently larger than the parasitic capacitances C_{P1} and C_{P2}, the noise current ICM1 and ICM2 are represented as equations (1) and (2).

ICM1=C_{P1}×dVCM/dt (1)

ICM2=C_{P2}×dVCM/dt (2)

Herein, the common mode voltage VCM makes the cathode of the light emitting element 2 be positive.

When the common mode voltage VCM rises, the noise current ICM1 flows in an opposite direction to the optical current IF, and the noise current ICM2 flows in an opposite direction to the reference current IR. As a result, the pair of voltages PD1 and DM1 of the amplifier 6 varies in an opposite direction to an ordinary operation and is lower than the voltage value in the unsignalized state.

The first compensator 11 suppresses the drop of the voltages PD1 and DM1 by supplying current to for example, the output terminal of the amplifier 6 when the pair of voltages PD1 and DM1 of the amplifier 6 are lower than the voltage value in the unsignalized state. In addition, the first compensator 11 clamps for example, the pair of voltages PD1 and DM1 to a predetermined value CM1 or more, which is lower than the voltage value in the unsignalized state. As a result, the amplifier 6 is held on an operating point where the amplifier 6 is not saturated but operable. Moreover, when the noise currents ICM1 and ICM2 by the common-mode noise CM do not flow, the amplifier 6 returns to an original operating point.

When the common mode voltage VCM drops, the noise current ICM1 flows in the same direction as the optical current IF, and the noise current ICM2 flows in the same direction as the reference current IR. As a result, the voltages PD1 and

DM1 of the amplifier 6 vary in the same direction as a normal operation to receive the optical signal OF, and are higher than the voltage value in the unsignalized state. Since the variation of the voltages PD1 and DM1 is in the same direction as the normal operation to receive the optical signal OF, when the variation of the voltages PD1 and DM1 is within a range in which the amplifier 6 is operable, the amplifier 6 is not saturated. When the noise currents ICM1 and ICM2 do not flow, the amplifier 6 returns to the original operating point.

As such, in the photo-coupling type insulated circuit 1, even though the pair of voltages PD1 and DM1 of the amplifier 6 is changed by the application of the common-mode noise CM, the amplifier 6 is not saturated, and as a result, the magnitude relationship between the voltage PD1 and the voltage DM1 is not changed. As a result, H and L are not incorrectly output due to the incorrect operation of the comparator 9, and tolerance of the common-mode noise CM of the light receiving circuit 3 may be improved.

For example, in the case where the first compensator 11 is not provided, when the common-mode noise CM is applied, the amplifier 6 may be saturated. In addition, when the amplifier 6 returns to the operable operating point, the magnitude relationship between the pair of voltages PD1 and DM1 may be changed. As a result, in the case where the first compensator 11 is not provided, the comparator 9 may incorrectly output H and L, and the tolerance of the common-mode noise CM is limited.

Further, even when the first compensator 11 is not provided, an operating range of the amplifier 6 is extended so as to prevent the amplifier 6 from being saturated by the noise currents ICM1 and ICM2, and further, responsiveness to the noise currents ICM1 and ICM2 is ensured by speeding up the amplifier 6, to thereby improve the noise tolerance. However, when the operating range of the amplifier 6 is extended, that is, a dynamic range is extended, receiving sensitivity and a signal-to-noise ratio (S/N) of the light receiving circuit 3 deteriorate. Further, in order to speed up the amplifier 6, a bias current need to be increased, and power consumption increases.

In this regard, in the embodiment, when the common-mode noise CM is applied, the first compensator 11 is held on the operating point where the amplifier 6 is not saturated. As a result, since the magnitude relationship between the pair of voltages PD1 and DM1 of the amplifier 6 is not changed, the noise tolerance in which the comparator 9 does not perform incorrect output may be improved.

Further, in the embodiment, since the operating range of the amplifier 6 for the optical signal OF is not changed by the first compensator 11, the receiving sensitivity or S/N may not deteriorate.

Moreover, in the embodiment, since power consumption in the normal operation of the first compensator 11 is little, the power consumption may not be increased. Further, even in the unsignalized state, biasing so that current flows in the first compensator is to improve the response for the common-mode noise CM.

Next, a second embodiment will be described.

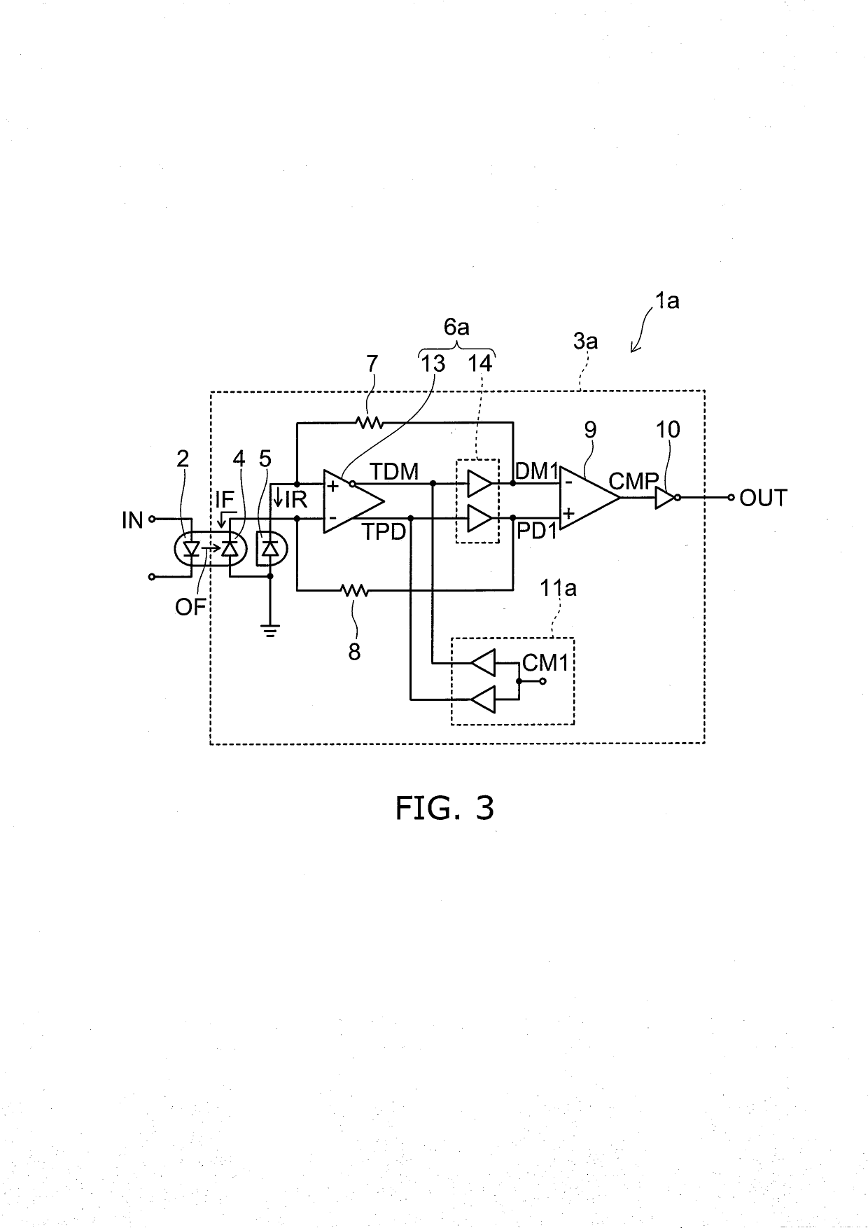

FIG. 3 is a block diagram illustrating a photo-coupling type insulated circuit including a light receiving circuit according to the second embodiment.

As illustrated in FIG. 3, a photo-coupling type insulated circuit 1a includes the light emitting element 2 and a light receiving circuit 3a. The second embodiment is different from the first embodiment in configurations of the amplifier 6 and the first compensator 11. That is, in the photo-coupling type insulated circuit 1a according to the second embodiment, an amplifier 6a and a first compensator 11a are provided instead of the amplifier 6 and the first compensator 11 according to the first embodiment, respectively. Components other than the amplifier 6a and the first compensator 11a of the light receiving circuit 3a disclosed in the second embodiment are the same as those of the light receiving circuit 3 disclosed in the first embodiment.

The amplifier 6a includes a first amplifier 13 converting the optical current IF and the reference current IR into voltages, and a second amplifier 14 connected in cascade to the first amplifier 13.

The first amplifier 13 is a differential amplifier. The first amplifier 13 converts the optical current IF output from the light receiving element 4 and the reference current IR output from the reference element 5 into the voltages, which are amplified. A voltage TPD acquired by converting the optical current IF and a voltage TDM acquired by converting the reference current IR are output to a pair of output terminals of the first amplifier 13, respectively. When the optical current IF which flows toward the light receiving element 4 from one input terminal (−terminal) of the first amplifier 13 increases, the voltage TPD of the amplifier 13 rises. Further, when the reference current IR which flows toward the reference element 5 from the other input terminal (+terminal) of the amplifier 13 increases, the voltage TDM rises. Further, the first amplifier 13 may convert the optical current IF and the reference current IR into the voltages, respectively, and a singular configuration is arbitrary.

The second amplifier 14 is for example, a buffer amplifier in which a gain is set to unity. The second amplifier 14 inputs the pair of voltages TPD and TDM of the first amplifier 13 and outputs the pair of voltages PD1 and DM1. A pair of output terminals of the second amplifier 14 is connected to the feedback resistors 7 and 8 and the comparator 9 as a pair of output terminals of the amplifier 6a.

The first compensator 11a is different from the first compensator 11 according to the first embodiment in the connected output terminal. That is, the first compensator 11a is connected to the pair of output terminals of the first amplifier 13 and the pair of input terminals of the second amplifier 14.

The first compensator 11a suppresses voltage variation in an opposite direction to the direction in which the voltage TPD of the first amplifier 13 varies when the optical current IF increases.

In the embodiment, when the common-mode noise CM is applied, the first compensator 11a holds the first amplifier 13 on the operating point where the first amplifier 13 is not saturated, and as a result, the second amplifier 14 is held on an operating point where the second amplifier 14 is not also saturated. As a result, since the magnitude relationship between voltages of the second amplifier 14, that is, the pair of voltages PD1 and DM1 of the amplifier 6a is not changed, the noise tolerance in which the comparator 9 does not perform incorrect output may be improved.

Further, in the embodiment, since the amplifier 6a is constituted by two stages of the first amplifier 13 and the second amplifier 14, the range in which the amplifier 6a is not saturated but operable, that is, a variation range of the pair of voltages PD1 and DM1 may be extended. As a result, the noise tolerance in which the comparator 9 does not perform incorrect output may be further improved.

An effect of the embodiment other than above is the same as the first embodiment.

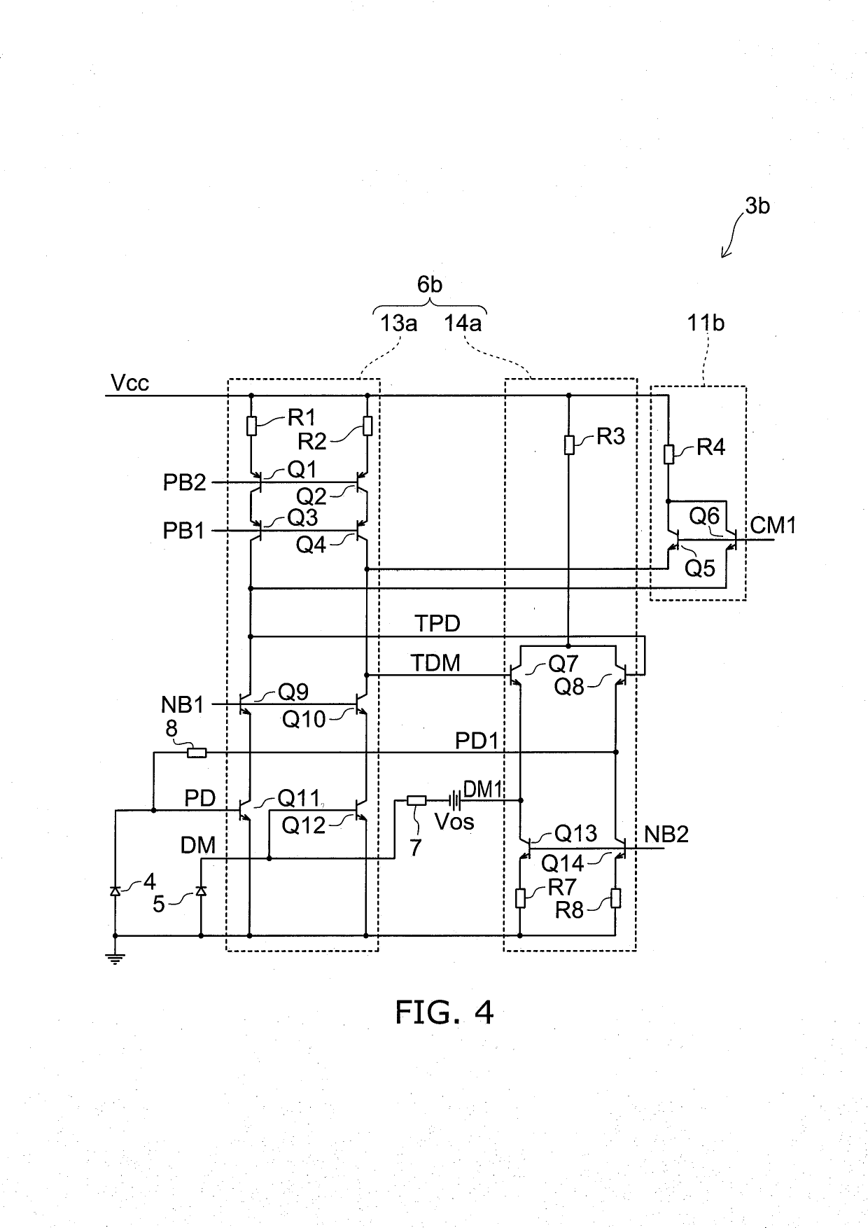

FIG. 4 is a circuit diagram illustrating a light receiving circuit according to the second embodiment.

As illustrated in FIG. 4, a light receiving circuit 3b includes the light receiving element 4, the reference element 5, the amplifier 6b that converts the optical current IF of the light receiving element 4 and the reference current IR of the reference element 5 into the voltages, respectively, the feedback resistors 7 and 8, and the first compensator 11b. Further, the comparator 9 and the waveform shaper 10 will not be described.

The amplifier 6b includes a first amplifier 13a converting the optical current IF and the reference current IR into the voltages, respectively and a second amplifier 14a connected in cascade to the first amplifier 13a.

The first amplifier 13a is the differential amplifier and includes resistors R1 and R2, an active load constituted by transistors Q1 to Q4, and a cascode amplifier constituted by Q9 to Q11.

An emitter of the transistor Q1 is connected to a power supply Vcc through the resistor R1, a bias voltage PB2 is supplied to a base of the transistor Q1, and a collector of the transistor Q1 is connected to an emitter of the transistor Q3. A bias voltage PB1 is supplied to a base of the transistor Q3, and a collector of the transistor Q3 is connected to a collector of the transistor Q9. An emitter of the transistor Q2 is connected to the power supply Vcc through the resistor R2, the bias voltage PB2 is supplied to a base of the transistor Q2, and a collector of the transistor Q2 is connected to an emitter of the transistor Q4. The bias voltage PB1 is supplied to a base of the transistor Q4, and a collector of the transistor Q4 is connected to a collector of the transistor Q10. Further, the transistors Q1 to Q4 are PNP transistors.

A bias voltage NB1 is supplied to a base of the transistor Q9, and an emitter of the transistor Q9 is connected to a collector of the transistor Q11. A base of the transistor Q11 is connected to a cathode of the light receiving element 4, and an emitter of the transistor Q11 is connected to an anode of the light receiving element 4 and grounded to an output side thereof. Further, the bias voltage NB1 is supplied to a base of the transistor Q10, and an emitter of the transistor Q10 is connected to a collector of the transistor Q12. A base of the transistor Q12 is connected to a cathode of the reference element 5, and an emitter of the transistor Q12 is connected to an anode of the reference element 5 and grounded to the output side thereof. Further, the transistors Q9 to Q12 are NPN transistors.

In the first amplifier 13a, the optical current IF is supplied to the feedback resistor 8 connected to the base of the transistor Q11 and further, the reference current IR is supplied to the feedback resistor 7 connected to the base of the transistor Q12. In addition, the cascode-amplified voltage TPD acquired by converting the optical current IF into the voltage is output to the collector of the transistor Q9 and the collector of the transistor Q3. The cascode-amplified voltage TDM acquired by converting the reference current IR into the voltage is output to the collector of the transistor Q10 and the collector of the transistor Q4.

The second amplifier 14a includes the resistor R3, the transistors Q7 and Q8 constituting a differential pair, and the transistors Q13 and Q14 and the resistors R7 and R8 constituting the active load.

A collector of the transistor Q7 is connected to the power supply Vcc through the resistor R3, a base of the transistor Q7 is connected to the collector of the transistor Q10 and the collector of the transistor Q4, and an emitter of the transistor Q7 is connected to a collector of the transistor Q13. A collector of the transistor Q8 is connected to the power supply Vcc through the resistor R3, a base of the transistor Q8 is connected to the collector of the transistor Q9 and the collector of the transistor Q3, and an emitter of the transistor Q8 is connected to a collector of the transistor Q14.

A bias voltage NB2 is supplied to a base of the transistor Q13, and an emitter of the transistor Q13 is grounded to the output side through the resistor R7. The bias voltage NB2 is supplied to a base of the transistor Q14, and an emitter of the transistor Q14 is grounded to the output side through the resistor R8. Further, the transistors Q7, Q8, Q13, and Q14 are the NPN transistors.

As such, in the second amplifier 14a, the voltage TDM of the first amplifier 13a is input into a base of the transistor Q7 and thus, the voltage DM1 is output from an emitter of the transistor Q7 as an output voltage of the amplifier 6b. Further, the voltage TPD of the first amplifier 13a is input into a base of the transistor Q8 and thus, the voltage PD1 is output from an emitter of the transistor Q8 as the output voltage of the amplifier 6b. Further, the transistors Q7 and Q8 constitute emitter followers.

The feedback resistor 7 is connected between the base of the transistor Q12 and the emitter of the transistor Q7 through an offset voltage Vos. The feedback resistor 8 is connected between the base of the transistor Q11 and the emitter of the transistor Q8. Further, the offset voltage Vos is set to a voltage value in which the magnitude relationship between the pair of voltages TPD and TDM of the first amplifier 13a in the unsignalized state is not changed due to a manufacturing disparity. For example, the voltage value is 20 mV.

The first compensator 11b includes the resistor R4, and the transistors Q5 and Q6.

A collector of the transistor Q5 is connected to the power supply Vcc through the resistor R4, a predetermined value CM1 is supplied to a base of the transistor Q5, and an emitter of the transistor Q5 is connected to an output of the first amplifier 13a, that is, the collector of the transistor Q10 and the collector of the transistor Q4. A collector of the transistor Q6 is connected to the power supply Vcc through the resistor R4, the predetermined value CM1 is supplied to a base of the transistor Q6, and an emitter of the transistor Q6 is connected to an output of the first amplifier 13a, that is, the collector of the transistor Q9 and the collector of the transistor Q3. Further, the transistors Q5 and Q6 are the NPN transistors.

Next, an operation of the light receiving circuit 3b will be described.

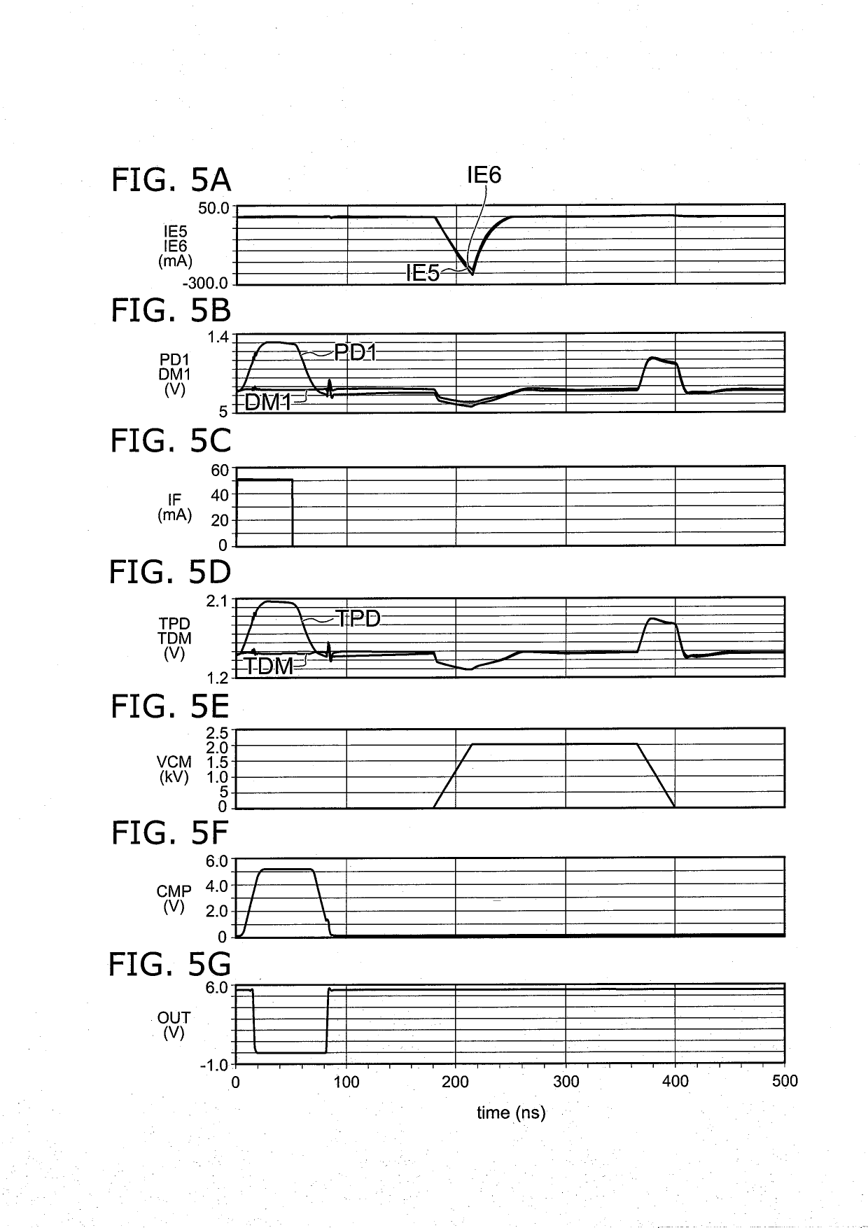

FIGS. 5A to 5G are waveform diagrams of signals of the light receiving circuit according to the second embodiment, FIG. 5A is emitter currents IE5 and IE6 of the transistors Q5 and Q6, FIG. 5B is the voltages PD1 and DM1 of the amplifier 6b, FIG. 5C is the optical current IF, FIG. 5D is the voltages TPD and TDM of the first amplifier 13a, FIG. 5E is the common mode voltage VCM, FIG. 5F is the output signal CMP of the comparator 9, and FIG. 5G is the output signal OUT of the waveform shaper 10.

Further, FIGS. 5A to 5G are simulation results in which the simulation model illustrated in FIG. 2 is applied to the light receiving circuit 3b, and as a simulation condition, the capacitance C_{L}=100 pF, the parasitic capacitance C_{P}=0.8 pF, and the parasitic capacitance C_{P1}=Cp₂=0.1 fF. Further, the common-mode noise CM is a pulse voltage (trapezoidal wave) in which the common mode voltage VCM is 2.0 kV, and both a rising time and a dropping time are 35 ns, and a change ratio of dVCM/dt is equivalent to 57 kV/μs.

First, a normal operation when the voltage VCM of the common-mode noise CM is zero will be described (FIG. 5E).

When the optical current IF increases at time=0 ns (FIG. 5C), the voltage of the light receiving element 4 drops and the base voltage PD of the transistor Q11 drops. As a result, the cascode amplifier of the transistors Q9 and Q11 raises the voltage TPD of the first amplifier 13a (FIG. 5D). Further, the optical current IF is supplied from the second amplifier 14a through the feedback resistor 8, and negatively fed back so as to prevent the voltage of the light receiving element 4 from dropping. Further, since the reference current IR is zero, the voltage of the reference element 5 is not changed, and the base voltage DM of the transistor Q12 is not changed. Therefore, the cascode amplifier of the transistors Q10 and Q12 outputs a value in the unsignalized state as the voltage TDM of the first amplifier 13a (FIG. 5D).

The transistor Q8 of the second amplifier 14a constitutes an emitter follower having the transistor Q14 and the resistor R8 as the loads. Since the voltage TPD input into the base of the transistor Q8 rises, the transistor Q8 raises the voltage PD1 (FIG. 5B). The transistor Q7 of the second amplifier 14a constitutes an emitter follower having the transistor Q13 and the resistor R7 as the loads. Since the voltage TDM does not vary as a value in the unsignalized state, the transistor Q7 outputs a value in the unsignalized state as the voltage DM1 (FIG. 5B).

The comparator 9 outputs H when the voltage PD1 is higher than the voltage DM1 (FIG. 5F). Further, the waveform shaper 10 outputs L by inverting the output CMP of the comparator 9 (FIG. 5G).

Next when the optical current IF returns to zero at time=50 ns (FIG. 5C), the voltage of the light receiving element 4 rises, and the base voltage PD of the transistor Q11 rises to a value in the unsignalized state. As a result, the cascode amplifier of the transistors Q9 and Q11 drops the voltage TPD (FIG. 5D).

Since the voltage TPD input into the base of the transistor Q8 drops, the transistor Q8 drops the voltage PD1 (FIGS. 5B and 5D). Further, since the reference current IR is zero, the voltage TDM and the voltage DM1 are values in the unsignalized state (FIGS. 5B and 5D).

The comparator 9 outputs L because the voltage PD1 returns to a value in the unsignalized state (FIG. 5F). Further, the waveform shaper 10 outputs H by inverting the output CMP of the comparator 9 (FIG. 5G).

Next, an operation when the common-mode noise CM is applied while the optical current IF is zero will be described (FIG. 5E).

When the voltage VCM of the common-mode noise CM rises at time=180 ns (FIG. 5E), the noise current ICM1 flows to the base of the transistor Q11, and the base voltage PD of the transistor Q11 rises. As a result, the cascode amplifier of the transistors Q9 and Q11 drops the voltage TPD (FIG. 5D). Similarly, the noise current ICM2 (=ICM1) flows to the base of the transistor Q12 and thus, the cascode amplifier of the transistors Q10 and Q12 drops the voltage TDM (FIG. 5D). Further, since a current (sink current) input into the second amplifier 14a through the feedback resistors 7 and 8 is small, the noise currents ICM1 and ICM2 flow to the bases of the transistors Q11 and Q12, respectively.

When the voltage TPD drops, a voltage between the base and the emitter of the transistor Q5 of the first compensator 11b rises, and as a result, an absolute value of the emitter current IE5 of the transistor Q5 increases (FIG. 5A). Similarly, when the voltage TDM drops, a voltage between the base and the emitter of the transistor Q6 of the first compensator 11b rises, and as a result, an absolute value of the emitter current IE6 of the transistor Q6 increases (FIG. 5A). Further, in FIGS. 5A to 5G, a direction in which the emitter currents IE5 and IE6 of the transistors Q5 and Q6 flows to the transistor side from the outside is positive.

Since the absolute value of the emitter current IE5 of the transistor Q5 increases with the drop of the voltage TPD (FIGS. 5A and 5D), the increase of current supplied from the active load of the transistors Q1 and Q3 is suppressed. As a result, the drop of the voltage TPD is suppressed and the transistors Q9 and Q11 are held on an operating point where the transistors Q9 and Q11 are not saturated but operable (FIG. 5D). Similarly, since the absolute value of the emitter current IE6 of the transistor Q6 increases with the drop of the voltage TDM (FIGS. 5A and 5D), the increase of current supplied from the active load of the transistors Q2 and Q4 is suppressed. As a result, the drop of the voltage TDM is suppressed and the transistors Q10 and Q12 are held on an operating point where the transistors Q10 and Q12 are not saturated but operable (FIG. 5D).

Since the voltage TPD input into the base of the transistor Q8 of the second amplifier 14a drops, the transistor Q8 drops the voltage PD1 (FIG. 5B). Since the voltage TDM input into the base of the transistor Q7 drops, the transistor Q7 drops the voltage DM1 (FIG. 5B).

Since the voltages TPD and TDM are held on an operating point where the first amplifier 13 is not saturated but operable by the first compensator 11a, the drop of the voltages PD1 and DM1 is suppressed, and the second amplifier 14a is held on an operating point where the second amplifier 14a is not saturated but operable.

When the rise of the voltage VCM of the common-mode noise CM at time=215 ns stops, and the voltage VCM becomes 2.0 kV which is a steady state value (FIG. 5E), the noise current ICM1 (=ICM2) becomes zero. As a result, the base voltage PD of the transistor Q11 drops and the cascode amplifier of the transistors Q9 and. Q11 raises the voltage TPD to a voltage value in the unsignalized state (FIG. 5D). Similarly, the base voltage DM of the transistor Q12 drops and the cascode amplifier of the transistors Q10 and Q12 raises the voltage TDM to a voltage value in the unsignalized state (FIG. 5D).

Since the voltage TPD rises to the voltage value in the unsignalized state, the transistor Q8 raises the voltage PD1 to return the raised voltage to the value in the unsignalized state (FIGS. 5B and 5D). Since the voltage TDM rises to the voltage value in the unsignalized state, the transistor Q7 raises the voltage DM1 to return the raised voltage to the value in the unsignalized state (FIGS. 5B and 5D).

Since the first amplifier 13a and the second amplifier 14a are not saturated by the noise currents ICM1 and ICM2, the magnitude relationship when the voltages TDP and TDM return to the voltage values in the unsignalized state is not inverted. Further, the magnitude relationship when the voltages PD1 and DM1 return to the voltage values in the unsignalized state is not inverted. As a result, the comparator 9 outputs L equivalent to the value in the unsignalized state (FIG. 5F). Further, the waveform shaper 10 outputs H acquired by inverting the output CMP of the comparator 9 (FIG. 5G).

Next, when the voltage VCM of the common-mode noise CM drops at time=365 ns (FIG. 5E), the noise current ICM1 flows to the parasitic capacitance C_{P1} from the feedback resistor 8, and the base voltage PD of the transistor Q11 drops. As a result, the cascode amplifier of the transistors Q9 and Q11 raises the voltage TPD (FIG. 5D). Similarly, the noise current ICM2 (=ICM1) flows to the parasitic capacitance C_{P2} from the feedback resistor 7, and the base voltage DM of the transistor Q12 drops. As a result, the cascode amplifier of the transistors Q10 and Q12 raises the voltage TDM (FIG. 5D).

Since a direction in which the noise current ICM1 flows is the same as the direction in which the optical current IF flows, the voltages TPD and TDM of the first amplifier 13a vary in the same direction as the normal operation in which the optical current IF is input, and is higher than the voltage values in the unsignalized state (FIG. 5D). Since the voltages TPD and TDM vary in the same direction as the normal operation, when the voltages TPD and TDM are within the range in which the first amplifier 13a is operable, the first amplifier 13a is not saturated.

Since the voltage TPD rises, the transistor Q8 of the second amplifier 14a raises the voltage PD1 (FIG. 5B). Similarly, since the voltage TDM rises, the transistor Q7 of the second amplifier 14a raises the voltage DM1 (FIG. 5B).

When the voltage VCM of the common-mode noise CM is zero at time=400 ns (FIG. 5E), the noise current ICM1 and ICM2 do not flow.

The first amplifier 13a outputs the voltage value in the unsignalized state as the voltages TPD and TDM (FIG. 5D). As a result, the second amplifier 14a outputs the voltage value in the unsignalized state as the voltages PD1 and DM1 (FIG. 5B).

As such, in the light receiving circuit 3b, even though the common-mode noise CM is applied and thus, the voltages TPD and TDM and the voltages PD1 and DM1 of the amplifier 6a vary, the amplifier 6a constituted by the first amplifier 13a and the second amplifier 14a is not saturated. As a result, since the magnitude relationship between the voltage PD1 and the voltage DM1 is not changed and the comparator 9 does not incorrectly output H and L, tolerance of the common-mode noise CM of the light receiving circuit 3a may be improved.

Next, the light receiving circuit of a comparative example will be described.

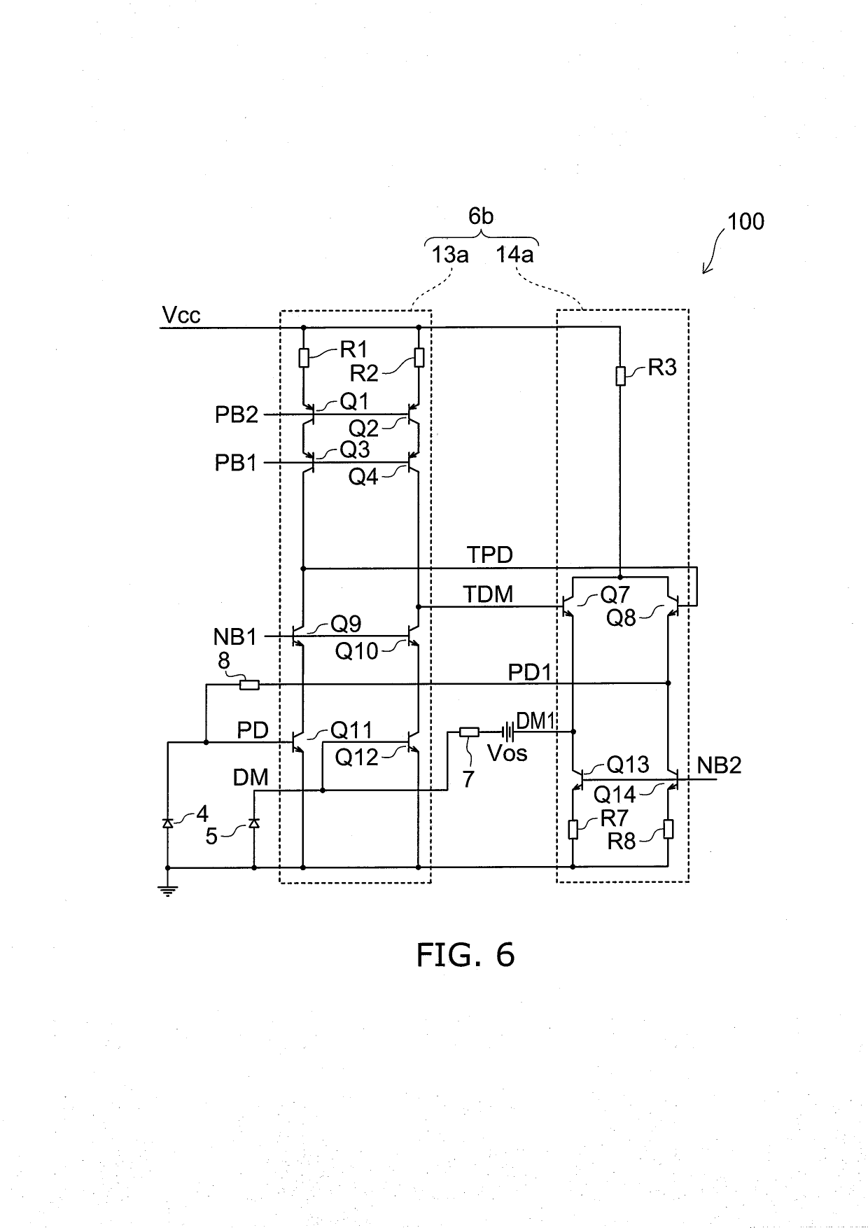

FIG. 6 is a circuit diagram of a light receiving circuit of a comparative example.

The light receiving circuit 100 according to the comparative example has a configuration in which the emitter of each of the transistors Q5 and Q6 of the first compensator 11b is opened, and corresponds to a configuration in which the first compensator 11b is deleted from the light receiving circuit 3b.

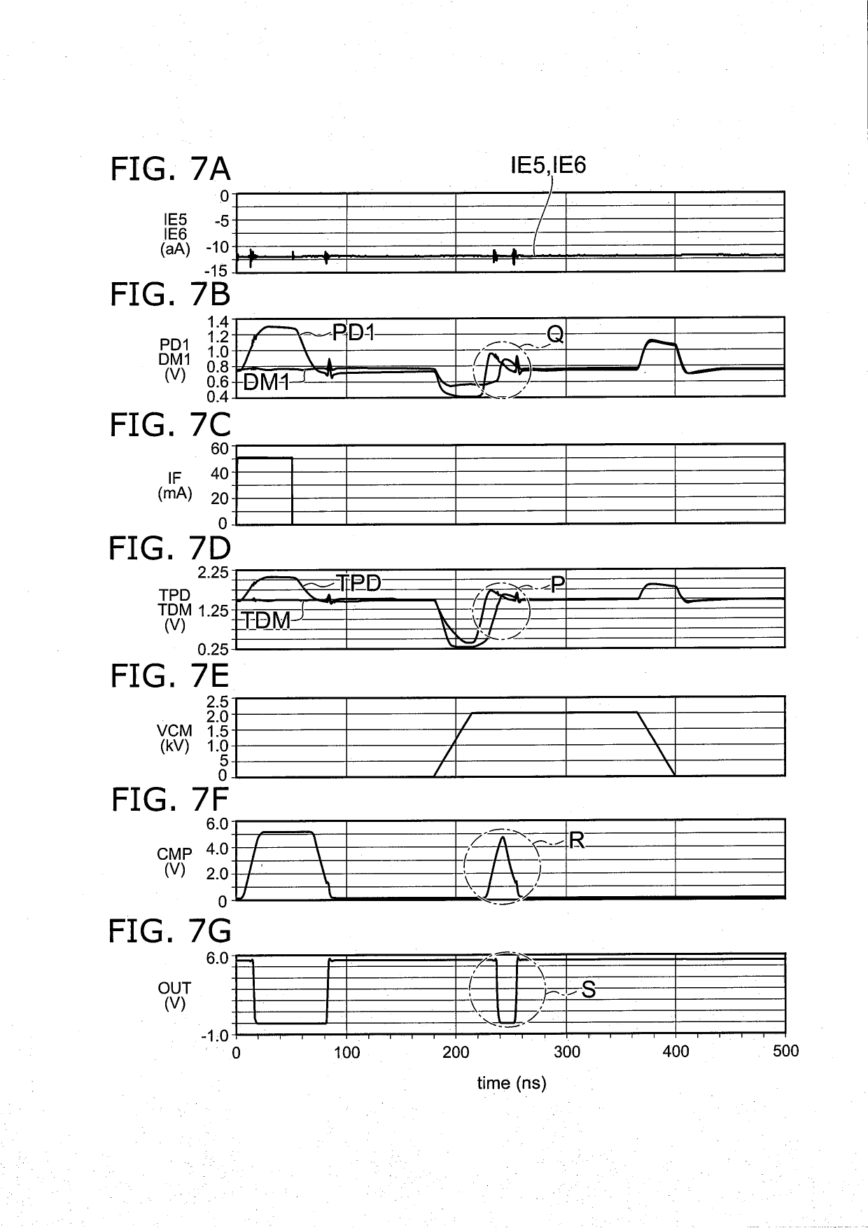

FIGS. 7A to 7G are waveform diagrams of signals of the comparative example, FIG. 7A is emitter currents IE5 and IE6 of the transistors Q5 and Q6, FIG. 7B is the voltages PD1 and DM1 of the amplifier 6b, FIG. 7C is the optical current IF, FIG. 7D is the voltages TPD and TDM of the first amplifier 13a, FIG. 7E is the common mode voltage VCM, FIG. 7F is the output signal CMP of the comparator 9, and FIG. 7G is the output signal OUT of the waveform shaper 10.

In the comparative example, since the emitter of each of the transistors Q5 and Q6 is opened, the emitter currents IE5 and IE6 of the transistors Q5 and Q6 are zero (FIG. 7A). Further, the simulation condition is the same as that of FIGS. 5A to 5G.

Since the first compensator 11a does not influence the normal operation with respect to the optical current IF, the normal operation when the voltage VCM of the common-mode noise CM is zero is the same as that in the light receiving circuit 3b.

When the optical current IF is input at time=0 ns to 50 ns (FIG. 7C), the first amplifier 13a outputs a positive pulse as the voltage TPD and the voltage value in the unsignalized state as the voltage TDM, respectively (FIG. 7D). The second amplifier 14a outputs the positive pulse as the voltage PD1 and the voltage value in the unsignalized state as the voltages DM1, respectively (FIG. 7B).

The comparator 9 outputs the positive pulse as the output signal CMP by inputting the positive pulse as the voltage PD1 (FIG. 7F). Further, the waveform shaper 10 outputs a negative pulse acquired by inverting the output CMP of the comparator 9 as the output signal OUT (FIG. 7G).

Next, an operation when the common-mode noise CM is applied while the optical current IF is zero, will be described (FIG. 7E).

When the voltage VCM of the common-mode noise CM rises at time=180 ns (FIG. 7E), the noise current ICM1 flows to the feedback resistor 8 and the base voltage PD of the transistor Q11 rises. As a result, the cascode amplifier of the transistors Q9 and Q11 drops the voltage TPD (FIG. 7D). Similarly, the noise current ICM2 (=ICM1) flows to the feedback resistor 7 and thus, the cascode amplifier of the transistors Q10 and Q12 drops the voltage TDM (FIG. 7D).

In the comparative example, since the emitter current IE5 and IE6 are not supplied from the first compensator 11b, the voltage TPD drops, and as a result, the transistors Q9 and Q11 are saturated. Further, the voltage TDM drops, and as a result, the transistors Q10 and Q12 are saturated. That is, the first amplifier 13a is saturated and thus, deviates from the operating point where the first amplifier 13a is operable.

Since the voltage TPD input into the base of the transistor Q8 of the second amplifier 14a drops, the transistor Q8 drops the voltage PD1 (FIG. 7B). However, in the comparative example, since the voltage TPD drops and thus, the transistors Q9 and Q11 are saturated, the transistor Q8 is turned off. Since the voltage TDM input into the base of the transistor Q7 drops, the transistor Q7 drops the voltage DM1 (FIG. 7B). Similarly, since the transistors Q10 and Q12 are saturated, the transistor Q7 is turned off. That is, the second amplifier 14a is turned off and deviates from the operating point where the second amplifier 14a is operable.

When the rise of the voltage VCM of the common-mode noise CM at time=215 ns stops, and the voltage VCM becomes 2.0 K which is the steady state value (FIG. 7E), the noise current ICM1 (=ICM2) becomes zero. As a result, the base voltage PD of the transistor Q11 drops, and the cascode amplifier of the transistors Q9 and Q11 returns to the operating point where the cascode amplifier of the transistors Q9 and Q11 is operable and raises the voltage TPD to a voltage value in the unsignalized state (FIG. 7D). Similarly, the base voltage DM of the transistor Q12 drops, and the cascode amplifier of the transistors Q10 and Q12 returns to the operating point where the cascode amplifier is operable and raises the voltage TDM to a voltage value in the unsignalized state (FIG. 7D).

When the voltage TPD rises, the transistor Q8 returns to an operating point where the transistor Q8 is operable, and returns to a voltage value in the unsignalized state by raising the voltage PD1 (FIG. 7B). When the voltage TDM rises, the transistor Q7 returns to an operating point where the transistor Q7 is operable, and returns to a voltage value in the unsignalized state by raising the voltage DM1 (FIG. 7B).

When the first amplifier 13a returns to the operating point where the first amplifier 13a is operable from the saturated state and raises the voltages TDP and TDM to the voltage values in the unsignalized state, which are the steady state values, a period in which the magnitude relationship between the voltage TPD and TDM is inverted is generated (a part surrounded by a dashed line P of FIG. 7D). When the second amplifier 14a returns to the operating point where the second amplifier 13a is operable from the state where the second amplifier 14a is turned off, and raises the voltages PD1 and DM1 to the voltage values in the unsignalized state, which are the steady state values, a period in which the magnitude relationship between the voltage PD1 and DM1 is inverted is generated (a part surrounded by a dashed line P of FIG. 7B).

The comparator 9 outputs a pulse of H acquired by inverting the output L in the unsignalized state during a period in which the magnitude relationship between the voltages PD1 and DM1 is inverted and thus, the voltage PD1 is higher than the voltage DM1 (a part surrounded by a dashed line R of FIG. 7F). The waveform shaper 10 outputs a pulse of L acquired by inverting the output signal CMP of the comparator 9 (a part surrounded by a dashed line S of FIG. 7G).

Next, when the voltage VCM of the common-mode noise CM drops at time=365 ns (FIG. 7C), the light receiving circuit 100 is operated in the same manner as the light receiving circuit 3b.

The first amplifier 13a outputs positive pulses as the voltages TPD and TDM, respectively (FIG. 7D). In addition, the second amplifier 14a outputs positive pulses as the voltage PD1 and DM1, respectively (FIG. 7B).

When the voltage VCM of the common-mode noise CM drops, the voltage TPD and TDM of the first amplifier 13a vary in the same direction as the normal operation in which the optical current IF is input and are higher than the voltage values in the unsignalized state (FIG. 7D). Since the voltages TPD and TDM vary in the same direction as the normal operation, when the voltages TPD and TDM are within the range in which the first amplifier 13a is operable, the first amplifier 13a is not saturated.

Since the magnitude relationship between the voltage PD1 and DM1 is not inverted, the comparator 9 outputs L equivalent to the voltage values in the unsignalized state (FIG. 7F). Further, the waveform shaper 10 outputs H by inverting the output CMP of the comparator 9 (FIG. 7G).

As such, since the light receiving circuit according to the comparative example does not have the first compensator 11a, when the common-mode noise CM is applied and thus, the first amplifier 13a is saturated, the magnitude relationship between the voltages TPD and TDM is inverted and incorrectly output at the time of returning to the operating point where the first amplifier 13a is operable. Accordingly, in the light receiving circuit of the comparative example, the tolerance of the common-mode noise CM is limited.

In this regard, when the common-mode noise CM is applied, the first compensator 11a suppresses voltage variation in an opposite direction to the variation direction of the first amplifier 13a of the amplifier 6a when the optical current IF increases, in the detailed example. In addition, the first amplifier 13a is held on the operating point where the first amplifier 13a is not saturated. As a result, since the magnitude relationship between the pair of voltages PD1 and DM1 of the amplifier 6a is not changed, the noise tolerance in which the comparator 9 does not perform incorrect output may be improved.

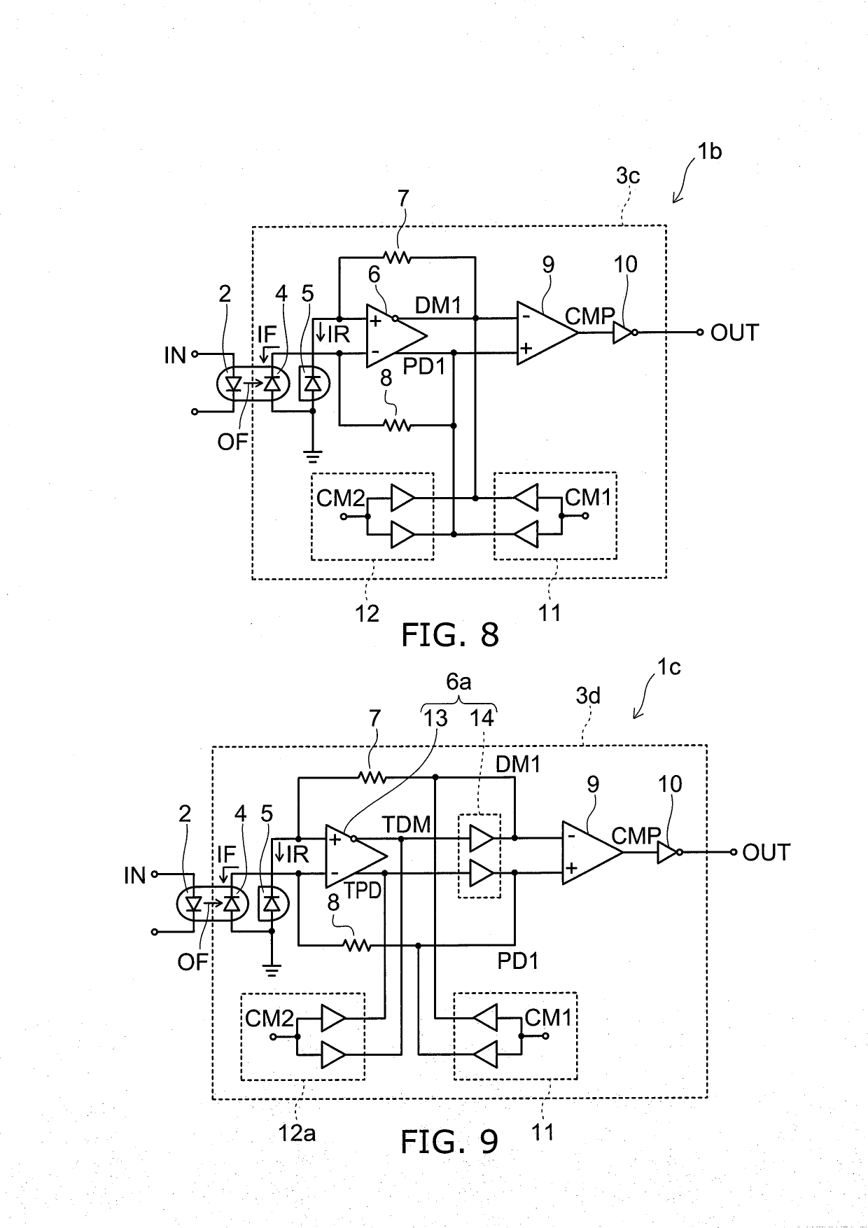

FIG. 8 is a block diagram illustrating a photo-coupling type insulated circuit including a light receiving circuit according to a third embodiment.

As illustrated in FIG. 8, a photo-coupling type insulated circuit lb includes the light emitting element 2 and a light receiving circuit 3c optically coupled with a light emitting element 2. The third embodiment is different from the first embodiment in that a second compensator 12 is added. Components other than the second compensator 12 of the light receiving circuit 3c according to the third embodiment are the same as those according to the first embodiment.

The second compensator 12 is connected to a pair of output terminals of the amplifier 6, and thus suppresses the voltage variation in the direction in which the voltage PD1 of the amplifier 6 varies when the optical current IF increases. That is, the second compensator 12 suppresses the voltage variation in the direction in which the pair of voltages PD1 and DM1 of the amplifier 6 are higher than the voltage value in the unsignalized state.

The second compensator 12 for example, suppresses the rise of the voltages PD1 and DM1 by receiving current to the output terminal, when the pair of voltages PD1 and DM1 of the amplifier 6 are higher than a predetermined value CM2. Herein, the predetermined value CM2 is a value within a range of the voltages PD1 and DM1 in which the amplifier 6 is not saturated but operable, and is for example, an operable maximum value. Further, the second compensator 12 is biased such that current flows a little even in the unsignalized state. In addition, the second compensator 12 is for example, the clamp circuit and clamps the pair of voltages PD1 and DM1 to the predetermined value CM2 or less.

For example, in the case where the second compensator 12 is not provided, when the common-mode noise CM is applied and the noise currents ICM1 and ICM2 which are larger than a tolerance of the optical current IF flow, the voltages PD1 and DM1 rise, and as a result, the amplifier 6 may be saturated. In addition, when the amplifier 6 returns to the operating point where the amplifier 6 is operable, the magnitude relationship between the pair of voltages PD1 and DM1 may vary. As a result, in the case where the second compensator 12 is not provided, since the comparator 9 may incorrectly output H and L, the tolerance of the common-mode noise CM may be limited.

In this regard, in the embodiment, when the common-mode noise CM is applied, the first compensator 11 suppresses voltage variation in an opposite direction to the variation direction of the voltage PD1 of the amplifier 6 when the optical current IF increases. The second compensator 12 suppresses voltage variation in the direction in which the voltage PD1 of the amplifier 6 varies when the optical current IF increases. That is, in the embodiment, since the first and second compensators 11 and 12 are held on the operating point where the amplifier 6 is not saturated in both directions in which the voltage drops and rises, the magnitude relationship between the pair of voltages PD1 and DM1 of the amplifier 6 is not changed. As a result, the noise tolerance in which the comparator 9 does not perform incorrect output may be further improved.

FIG. 9 is a block diagram illustrating a photo-coupling type insulated circuit including a light receiving circuit according to a fourth embodiment.

As illustrated in FIG. 9, a photo-coupling type insulated circuit 1c includes the light emitting element 2 and a light receiving circuit 3d optically coupled with the light emitting element 2. The fourth embodiment is different from the third embodiment in configurations of the amplifier 6 and the second compensator 12. That is, in the photo-coupling type insulated circuit 1c according to the fourth embodiment, an amplifier 6a and a second compensator 12a are provided instead of the amplifier 6 and the second compensator 12 according to the third embodiment, respectively. Components other than the amplifier 6a and the first compensator 12a of the light receiving circuit 3d according to the fourth embodiment are the same as those of the light receiving circuit 3c according to the third embodiment.

The amplifier 6a includes the first amplifier 13 converting the optical current IF and the reference current IR into voltages, respectively, and the second amplifier 14 connected in cascade to a first amplifier 13.

The first compensator 11 is connected to a pair of output terminals of the amplifier 6a, that is, an output of the second amplifier 14, and thus suppresses voltage variation in an opposite direction to a direction in which the voltage PD1 of the amplifier 6a varies when the optical current IF increases. Further, the amplifier 6a is the same as the amplifier 6a according to the second embodiment, and the first compensator 11 is the same as the first compensator 11 according to the first embodiment. Therefore, the amplifier 6a and the first compensator 11 will not be described.

The second compensator 12a is different from the second compensator 12 according to the third embodiment in connected output terminals. That is, the second compensator 12a is connected to a pair of output terminals of the first amplifier 13 and a pair of input terminals of the second amplifier 14.

The second compensator 12a suppresses voltage variation in the direction in which the voltage TPD of the first amplifier 13 varies when the optical current IF increases.

In the embodiment, when the common-mode noise CM is applied, the first compensator 11 suppresses voltage variation in an opposite direction to the variation direction of the voltage PD1 of the amplifier 6 when the optical current IF increases. The second compensator 12a suppresses voltage variation in the direction in which the voltage TPD of the first amplifier 13 of the amplifier 6a varies when the optical current IF increases. As a result, the voltage variation of the voltages PD1 and DM1 of the second amplifier 14 is suppressed. That is, in the embodiment, since the first and second compensators 11 and 12a hold the amplifier 6a on the operating point where the amplifier 6a is not saturated in both directions in which the voltage drops and rises, the magnitude relationship between the pair of voltages PD1 and DM1 of the amplifier 6a is not changed. As a result, the noise tolerance in which the comparator 9 does not perform incorrect output may be further improved.

Further, in the embodiment, since the amplifier 6a is constituted by two stages of the first amplifier 13 and the second amplifier 14, the range in which the amplifier 6a is not saturated but operable, that is, a variation range of the pair of voltages PD1 and DM1 may be extended. As a result, the noise tolerance in which the comparator 9 does not perform incorrect output may be further improved.

An effect of the embodiment other than above is the same as that of the third embodiment.

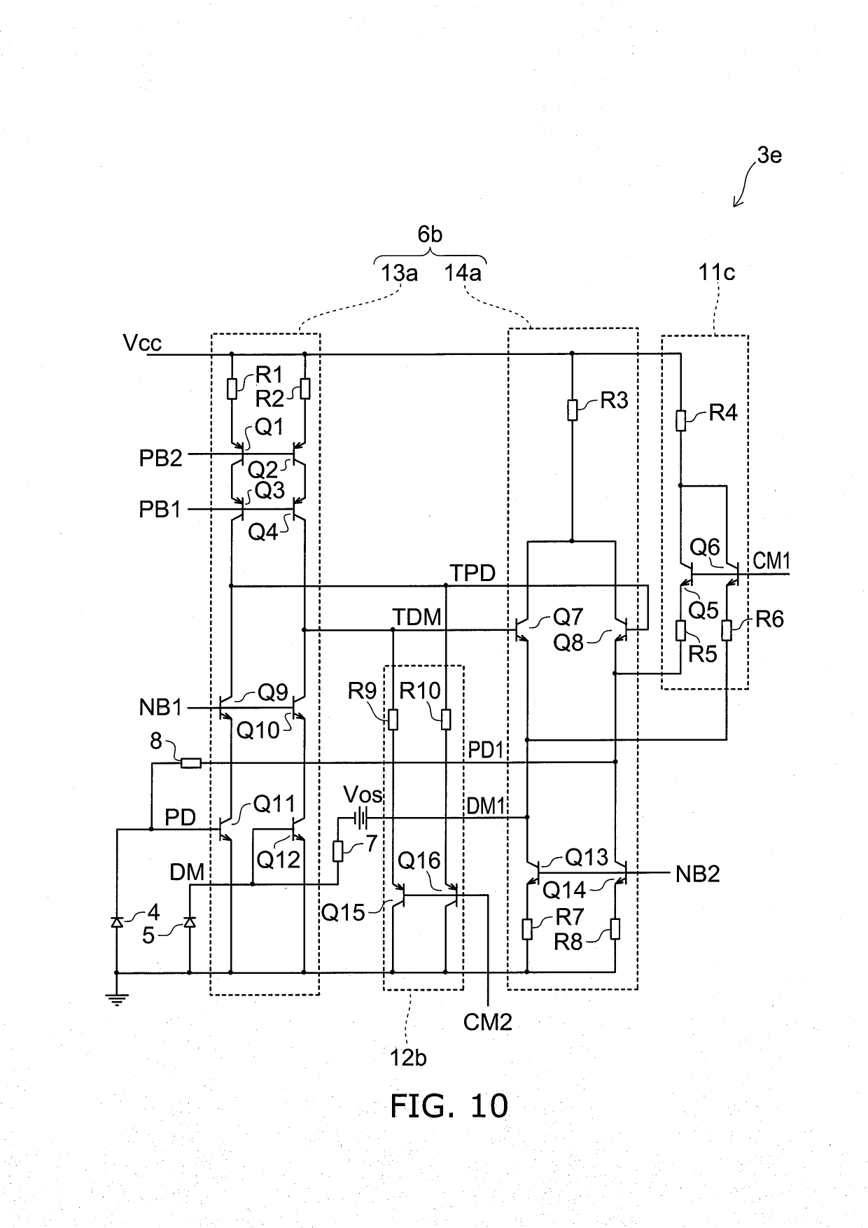

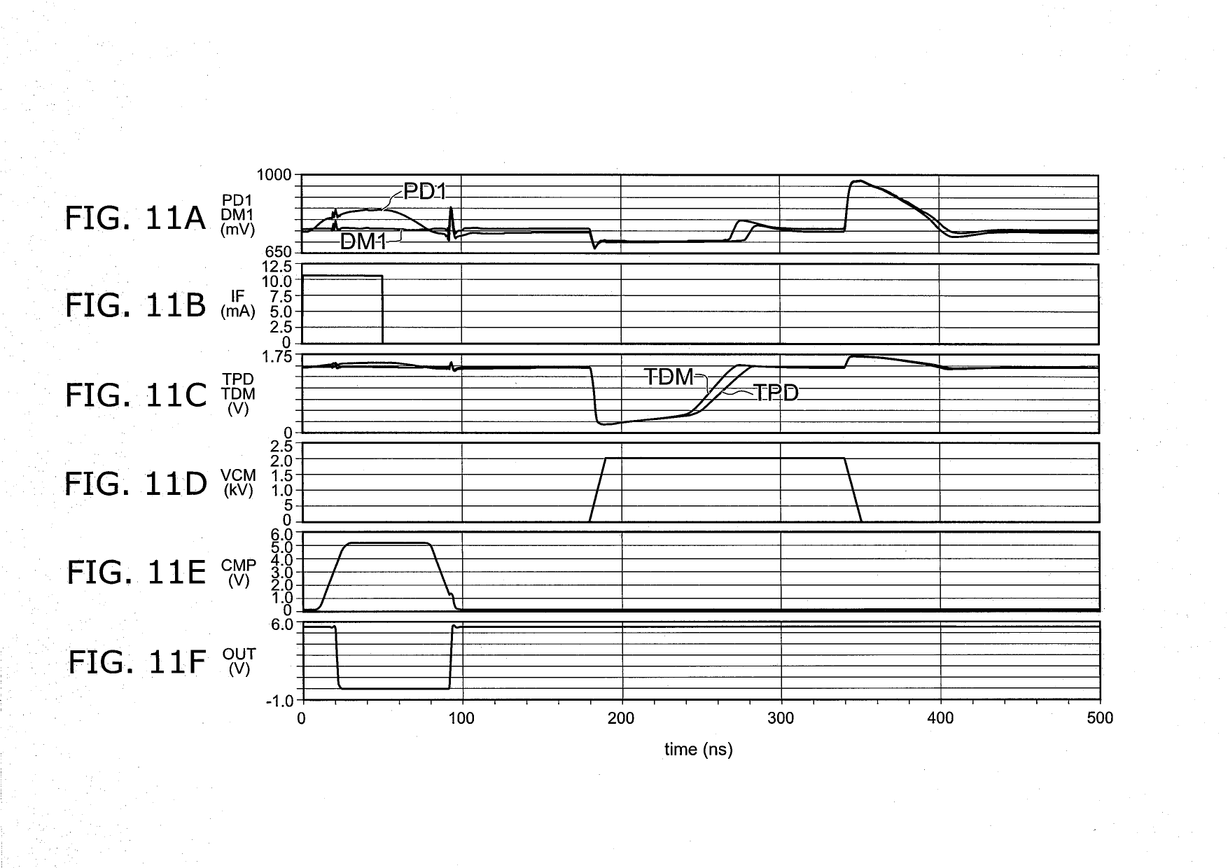

FIG. 10 is a circuit diagram illustrating a light receiving circuit according to the fourth embodiment.

As illustrated in FIG. 10, a light receiving circuit 3e according to the detailed example is different from the light receiving circuit 3b according to the detailed example of the second embodiment in that a first compensator 11c is provided instead of the first compensator 11b, and further, a second compensator 12b is added. That is, the light receiving circuit 3e includes the light receiving element 4, the reference element 5, the amplifier 6b that converts the optical current IF of the light receiving element 4 and the reference current IR of the reference element 5 into the voltage, respectively, the feedback resistors 7 and 8, the first compensator 11c, and the second compensator 12b, and a constant voltage source circuit 15. Components other than the first compensator 11c and the second compensator 12b are the same as those of the light receiving circuit 3b. Further, the comparator 9 and the waveform shaper 10 will not be described.

In the first compensator 11c, resistors R5 and R6 are added to the first compensator 11b. That is, the first compensator 11c includes the transistors Q5 and Q6 and the resistors R4 to R6. The emitter of the transistor Q5 is connected to the emitter of the transistor Q8 and the collector of the transistor Q14 through the resistor R5. The emitter of the transistor Q6 is connected to the emitter of the transistor Q7 and the collector of the transistor Q13 through the resistor R6.

The second compensator 12b includes resistors R9 and R10 and transistor Q15 and Q16.

An emitter of the transistor Q15 is connected to the collector of the transistor Q4 and the collector of the transistor Q10 of the first amplifier 13a in the amplifier 6a through the resistor R9, the predetermined value CM2 is supplied to a base of the transistor Q15, and the emitter of the transistor Q15 is grounded to the output side. An emitter of the transistor Q16 is connected to the collector of the transistor Q3 and the collector of the transistor Q9 of the first amplifier 13a in the amplifier 6a through the resistor R10, the predetermined value CM2 is supplied to a base of the transistor Q16, and the emitter of the transistor Q16 is grounded to the output side. Further, the transistors Q15 to Q16 are the PNP transistors.

Next, an operation of the photo-coupling type insulated circuit using the light receiving circuit 3e will be described.

FIGS. 11A to 11F are waveform diagrams of signals of the light receiving circuit according to the fourth embodiment,

FIG. 11A is the voltages PD1 and DM1 of the amplifier 6b, FIG. 11B is the optical current IF, FIG. 11C is the voltages TPD and TDM of the first amplifier 13a, FIG. 11d is the common mode voltage VCM, FIG. 11E is the output signal CMP of the comparator 9, and FIG. 11F is the output signal OUT of the waveform shaper 10.

Further, FIGS. 11A to 11F are simulation results in which the simulation model illustrated in FIG. 2 is applied to the light receiving circuit 3e and as a simulation condition, the capacitance C_{L}=100 pF, the parasitic capacitance C_{P}=0.8 pF, and the parasitic capacitance C_{P1}=C_{P2}=0.1 fF. Further, the common-mode noise CM is a pulse voltage (trapezoidal wave) in which the common mode voltage VCM is 2,0 kV, and both a rising time and a dropping time are 10 ns, and a change ratio dVCM/dt is equivalent to 200 kV/μs. In the simulation condition, the noise currents ICM1 and ICM2 are set to be larger than the optical current IF.

Since the second compensator 12b does not influence the normal operation with respect to the optical current IF, the normal operation when the voltage VCM of the common-mode noise CM is zero is the same as that in the light receiving circuit 3b.

When the optical current IF is input at time=0 ns to 50 ns (FIG. 11B), the first amplifier 13a outputs a positive pulse as the voltage TPD and the voltage value in the unsignalized state as the voltage TDM, respectively (FIG. 11C). In addition, the second amplifier 14a outputs a positive pulse as the voltage PD1 and the voltage value in the unsignalized state as the voltage DM1, respectively (FIG. 11A).

The comparator 9 inputs the positive pulse of the voltage PD1 and outputs the positive pulse (FIG. 11E). Further, the waveform shaper 10 outputs a negative pulse by inverting the output CMP of the comparator 9 (FIG. 11F).

Next, an operation when the common-mode noise CM is applied while the optical current IF is zero will be described (FIG. 11D).

When the voltage VCM of the common-mode noise CM rises at time=180 ns (FIG. 11D), the noise current ICM1 flows to the base of the transistor Q11, and the base voltage PD of the transistor Q11 rises. As a result, the cascode amplifier of the transistors Q9 and Q11 drops the voltage TPD (FIG. 11C). Similarly, the noise current ICM2 (=ICM1) flows to the base of the transistor Q12, and the cascode amplifier of the transistors Q10 and Q12 drops the voltage TDM (FIG. 11C). Further, since the current (sink current) input into the second amplifier 14a through the feedback resistors 7 and 8 is small, the noise currents ICM1 and ICM2 flow to the bases of the transistors Q11 and Q12, respectively.

Since the voltage TPD input into the base of the transistor Q8 of the second amplifier 14a drops, the transistor Q8 drops the voltage PD1 (FIG. 11A). Further, since the voltage TDM input into the base of the transistor Q7 drops, the transistor Q7 drops the voltage DM1 (FIG. 11A).

When the voltage PD1 drops, a voltage between the base and the emitter of the transistor Q5 of the first compensator 11c rises, and as a result, an absolute value of the emitter current IE5 of the transistor Q5 increases. Similarly, when the voltage DM1 drops, a voltage between the base and the emitter of the transistor Q6 of the first compensator 11c rises, and as a result, an absolute value of the emitter current IE6 of the transistor Q6 increases.

Since the absolute value of the emitter current IE5 of the transistor Q5 increases with the drop of the voltage PD1, the decrease of current supplied to an active load constituted by the transistor Q14 and the resistor R8 is suppressed. As a result, the drop of the voltage PD1 is suppressed and thus, the transistor Q8 is held on an operating point where the transistor Q8 is not saturated but operable (FIGS. 11A and 11C). Similarly, since the absolute value of the emitter current IE6 of the transistor Q6 increases with the drop of the voltage DM1, the decrease of current supplied to an active load constituted by the transistor Q13 and the resistor R7 is suppressed. As a result, the drop of the voltage DM1 is suppressed and thus, the transistor Q7 is held on an operating point where the transistor Q7 is not saturated but operable (FIGS. 11A and 11C).

When the rise of the voltage VCM of the common-mode noise CM at time=190 ns stops, and the voltage VCM becomes 2.0 K which is a steady state value (FIG. 11D), the noise current ICM1 (=ICM2) becomes zero. As a result, the base voltage PD of the transistor Q11 drops and the cascode amplifier of the transistors Q9 and Q11 raises the voltage TPD to a voltage value in the unsignalized state (FIG. 11C).

Similarly, the base voltage DM of the transistor Q12 drops and the cascode amplifier of the transistors Q10 and Q12 raises the voltage TDM to a voltage value in the unsignalized state (FIG. 11C).

The transistor Q8 raises the voltage PD1 to return the voltage PD1 to the voltage value in the unsignalized state (FIG. 11A). Further, the transistor Q7 raises the voltage DM1 to return the voltage DM1 to the voltage value in the unsignalized state (FIG. 11A).

Since the second amplifier 14a is not saturated by the noise currents ICM1 and ICM2, the magnitude relationship between the voltages PD1 and DM1 is not inverted when the voltages PD1 and DM1 return to the voltage values in the unsignalized state. As a result, the comparator 9 outputs L equivalent to the value in the unsignalized state (FIG. 11E). Further, the waveform shaper 10 outputs H acquired by inverting the output CMP of the comparator 9 (FIG. 11F).

Next, when the voltage VCM of the common-mode noise CM drops at time=340 ns (FIG. 11D), the noise current ICM1 flows to the parasitic capacitance C_{P1} from the feedback resistor 8 and the base voltage PD of the transistor Q11 drops. As a result, the cascode amplifier of the transistors Q9 and Q11 raises the voltage TPD (FIG. 11C). Similarly, the noise current ICM2 (=ICM1) flows to the parasitic capacitance C_{P1} from the feedback resistor 7, and the cascode amplifier of the transistors Q10 and Q12 raises the voltage TDM (FIG. 11C).

Since a direction in which the noise current ICM1 flows is the same as the direction in which the optical current IF flows, the voltages TPD and TDM of the first amplifier 13a vary in the same direction as the normal operation in which the optical current IF is input and are higher than the voltage values in the unsignalized state (FIG. 11C). Further, since the noise currents ICM1 and ICM2 are larger than the optical current IF, the voltages rise to higher voltages than those when the optical signal IF is input (FIG. 11C).

Since the voltage TPD rises, current that flows on the transistor Q16 in the second compensator 12b increases. As a result, the decrease of current that flows on an active load constituted by the transistor Q1 and Q3 is suppressed, and the rise of the voltage TPD is suppressed. The voltage TPD is clamped to the predetermined value CM2 within a range in which a cascode amplifier constituted by the transistors Q9 and Q11 is operable. Further, since the voltage TDM rises, current that flows on the transistor Q15 in the second compensator 12b increases. As a result, the decrease of current that flows on an active load constituted by the transistor Q2 and Q4 is suppressed, and the rise of the voltage TDM is suppressed. The voltage TDM is clamped to the predetermined value CM2 within a range in which a cascode amplifier constituted by the transistors Q10 and Q12 is operable.

As such, variation of the voltages TPD and TDM is suppressed by the second compensator 12b. The first amplifier 13a is held on an operating point where the first amplifier 13a is not saturated but operable.

Further, since the voltage TPD rises, the transistor Q8 of the second amplifier 14a raises the voltage PD1 (FIG. 11A). Similarly, since the voltage TDM rises, the transistor Q7 of the second amplifier 14a raises the voltage DM1 (FIG. 11A). In this case, since the first amplifier 13a is not saturated, the second amplifier 14a is also held on an operating point where the second amplifier 14a is not saturated but operable.

When the voltage VCM of the common-mode noise CM is zero at time=350 ns (FIG. 11D), the noise currents ICM1 and ICM2 do not flow.

The first amplifier 13a outputs the voltage value in the unsignalized state as the voltages TPD and TDM (FIG. 11C). As a result, the second amplifier 14a outputs the voltage value in the unsignalized state as the voltages PD1 and DM1 (FIG. 11A).

Since the first amplifier 13a and the second amplifier 14a are not saturated when the noise currents ICM1 and ICM2 decrease, the magnitude relationship between the voltages TPD and TDM is not inverted when the voltages TDP and TDM return to the voltage values in the unsignalized state. Further, the magnitude relationship between the voltages PD1 and DM1 is not inverted when the voltages PD1 and. DM1 return to the voltage values in the unsignalized state. As a result, the comparator 9 outputs L equivalent to the value in the unsignalized state (FIG. 11E). Further, the waveform shaper 10 outputs H acquired by inverting the output CMP of the comparator 9 (FIG. 11F).

As such, in the light receiving circuit 3e according to the detailed example, the common-mode noise CM is applied and thus, the voltages TPD and TDM and the voltages PD1 and DM1 of the amplifier 6a vary more largely than those when the optical current IF is input, however, the amplifier 6a is not saturated, and as a result, the magnitude relationship between the voltage PD1 and the voltage DM1 is not changed. Therefore, the comparator 9 does not perform incorrect output and tolerance of the common-mode noise CM of the light receiving circuit 3a may be further improved.

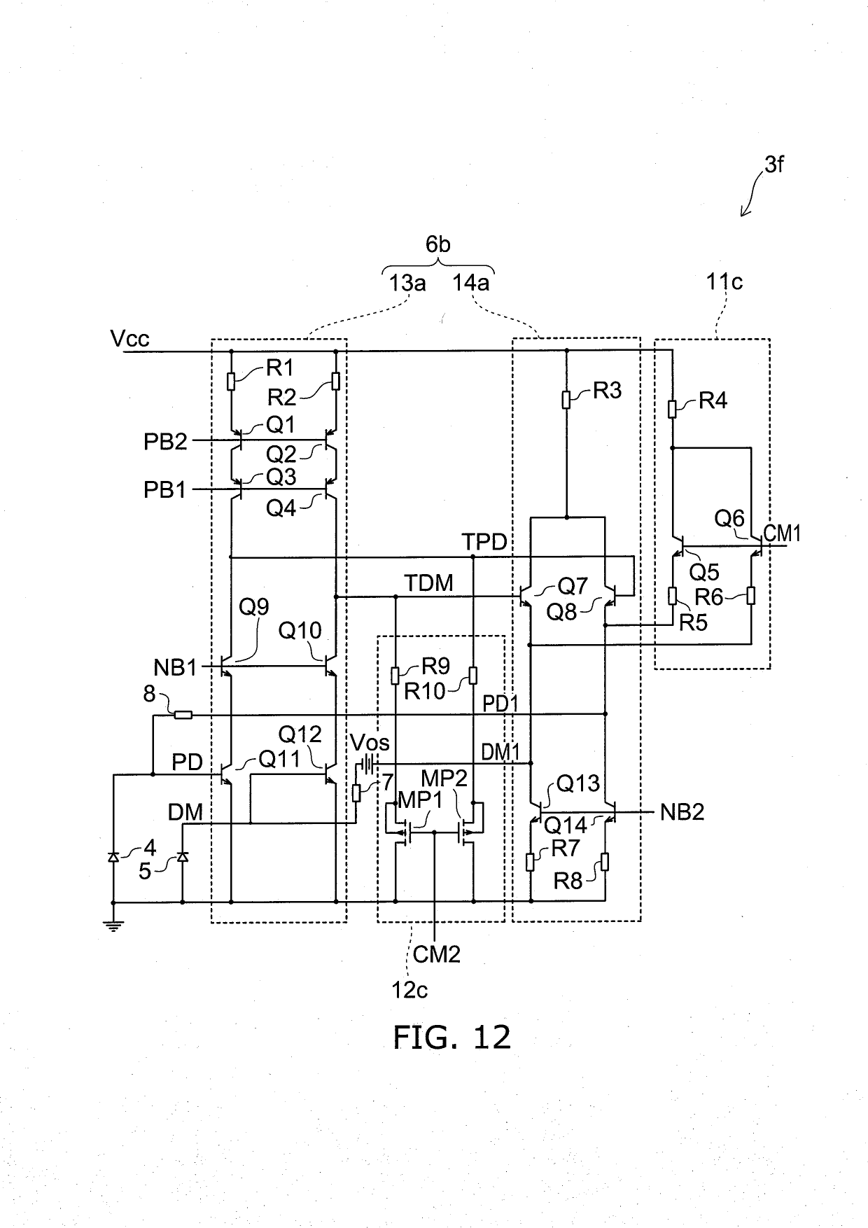

FIG. 12 is another circuit diagram illustrating a light receiving circuit according to the fourth embodiment.

The light receiving circuit 3f according to the detailed example is different from the light receiving circuit 3e in a configuration of the second compensator 12b. That is, in the light receiving circuit 3f, a second compensator 12c is provided instead of the second compensator 12b of the light receiving circuit 3e. Other components are the same as those of the light receiving circuit 3e.

Transistors MP1 and MP2 are provided in the second compensator 12c, instead of the transistors Q15 and Q16 in the second compensator 12b. The transistors MP1 and MP2 are P channel type MOSFETs (hereinafter, referred to as PMOS).

In the detailed example, since the second compensator 12b is configured by the PMOS, a propagation delay does not occur due to an accumulation time like a PNP transistor, and the increase of a propagation delay time when the first amplifier 13a is changed from H to L may be suppressed.

Other effects other than above are the same as those of the light receiving circuit 3e.

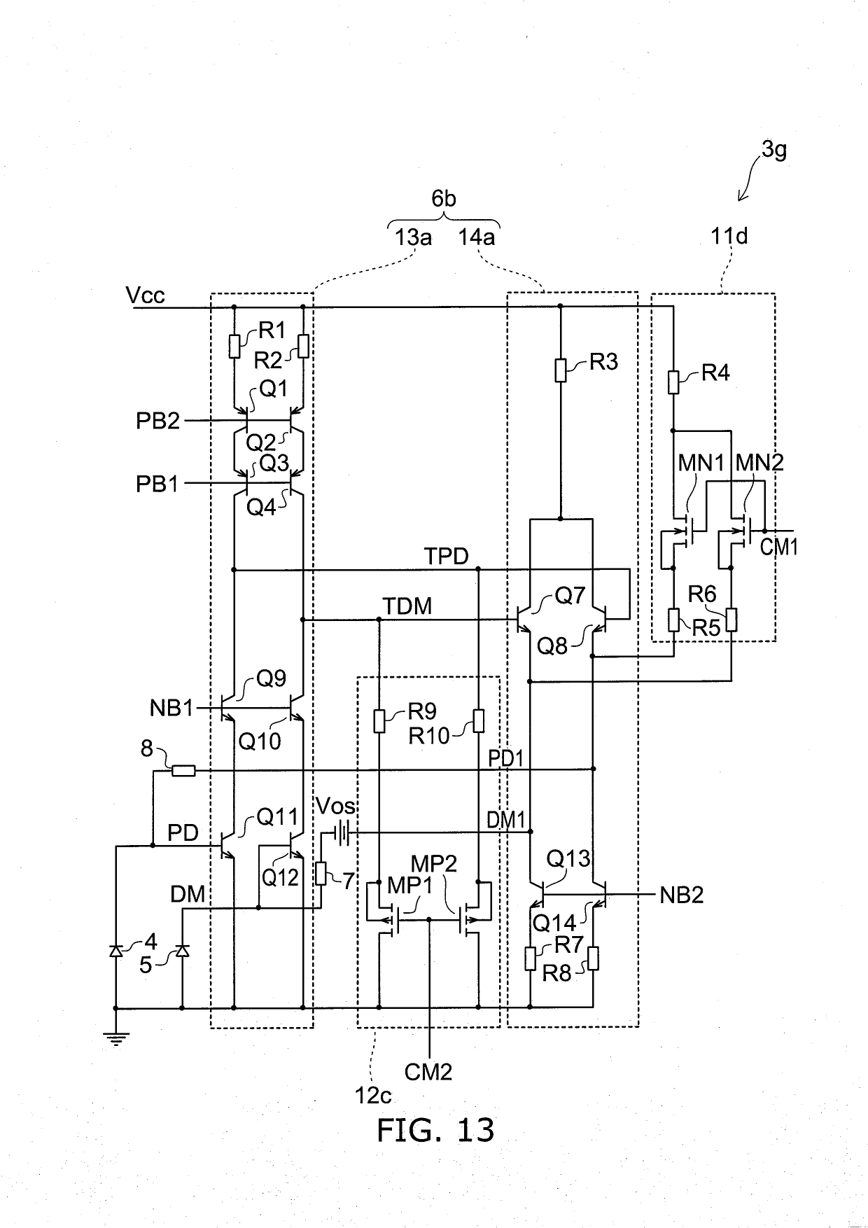

FIG. 13 is anther circuit diagram illustrating a light receiving circuit according to the fourth embodiment.

The light receiving circuit 3g according to the detailed example is different from the light receiving circuit 3f in a configuration of the first compensator 11c. That is, in the light receiving circuit 3g, a first compensator lid is provided instead of the first compensator 11c of the light receiving circuit 3f. Other components are the same as those of the light receiving circuit 3f.

Transistors MN1 and MN2 are provided in the first compensator 11d, instead of the transistors Q5 and Q6 in the first compensator 11c. The transistors MN1 and MP2 are N channel type MOSFETs (hereinafter, referred to as NMOS).

In the detailed example, since the first compensator 11d is configured by the NMOS, the propagation delay does not occur due to the accumulation time like an NPN transistor and the increase of the propagation delay time when the second amplifier 14 is changed from L to H may be suppressed.

Other effects other than above are the same as those of the light receiving circuit 3f.

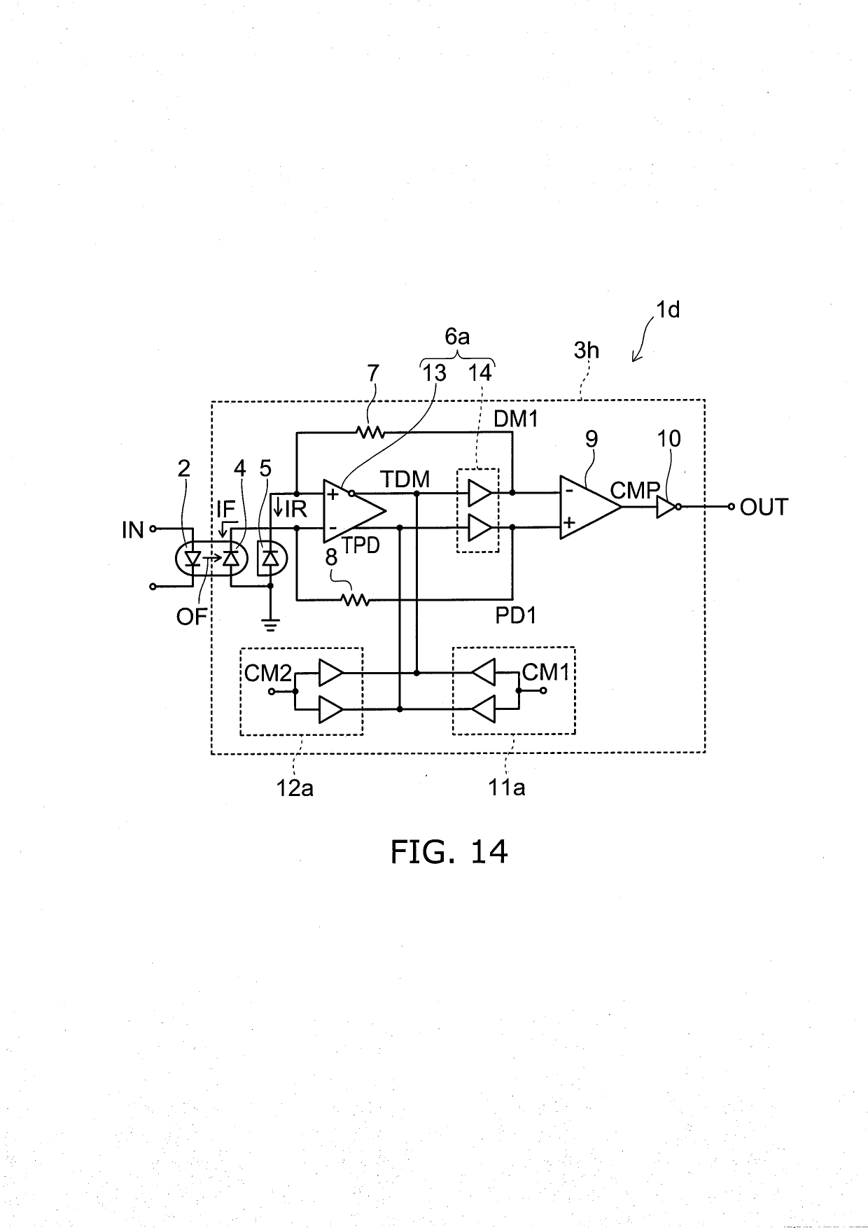

FIG. 14 is a block diagram illustrating a photo-coupling type insulated circuit including a light receiving circuit according to a fifth embodiment.

As illustrated in FIG. 14, a photo-coupling type insulated circuit id includes the light emitting element 2 and a light receiving circuit 3h optically coupled with the light emitting element 2. The fifth embodiment is different from the fourth embodiment in a configuration of the first compensator 11. That is, in the photo-coupling type insulated circuit 1d according to the fifth embodiment, a first compensator 11a is provided, instead of the first compensator 11 according to the fourth embodiment. Components other than the first compensator 11a of the light receiving circuit 3h according to the fifth embodiment are the same as those of the light receiving circuit 3d according to the fourth embodiment.

The first compensator 11a is different from the first compensator 11 in connected output terminals. That is, the first compensator 11a is to the same as the first compensator 11a according to the second embodiment, and is connected to a pair of output terminals of the first amplifier 13 and a pair of input terminals of the second amplifier 14. The first compensator 11a suppresses voltage variation in an opposite direction to the direction in which the voltage TPD of the first amplifier 13 varies when the optical current IF increases.

The second compensator 12a is the same as the second compensator 12a according to the fourth embodiment, and suppresses voltage variation in the direction in which the voltage TPD of the first amplifier 13 varies when the optical current IF increases.

In the embodiment, when the common-mode noise CM is applied, the first compensator 11a and the second compensator 12a hold the first amplifier 13 on the operating point where the first amplifier 13 is not saturated, and as a result, the second amplifier 14 is also held on an operating point where the second amplifier 14 is not saturated. As a result, since the magnitude relationship between voltages of the second amplifier 14, that is, the pair of voltages PD1 and DM1 of the amplifier 6a is not changed, the noise tolerance in which the comparator 9 does not perform incorrect output may be improved.

Further, since the first amplifier 13 and the second amplifier 14 constituting the amplifier 6a are not saturated, responsiveness at the time of returning from the common-mode noise CM is improved.

Effects other than above in the embodiment are the same as those of the fourth embodiment.

Further, in each embodiment, the configuration in which the optical current IF output from the light receiving element 4 flows from the feedback resistor 7 to the light receiving element 4 has been described. However, for example, a configuration in which the light receiving element 4 is connected between the power supply and the input terminal of the amplifier, and the optical current IF flows from the light receiving element 4 to the feedback resistor 7 may be provided.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A light receiving circuit, comprising:
a light receiving element configured to output an optical current by receiving an optical signal;
an amplifier configured to convert the optical current into a voltage and amplify the voltage; and
a first compensator connected to the amplifier and configured to suppress a variation in an opposite direction from a voltage variation of the amplifier when the optical current increases.

2. The circuit according to claim 1, further comprising
a second compensator connected to the amplifier and configured to suppress the variation in the direction of the voltage variation of the amplifier when the optical current increases.

3. The circuit according to claim 2, wherein
the amplifier includes a buffer amplifier set to a gain of unity, and
the second compensator is connected to an input of the buffer amplifier.

4. The circuit according to claim 3, wherein
the first compensator is connected to the input of the buffer amplifier.

5. The circuit according to claim 3, wherein
the first compensator is connected to an output of the buffer amplifier.

6. The circuit according to claim 1, further comprising
a reference element having electric characteristics with the light receiving element, shielded from the optical signal, and outputting a reference current.

7. The circuit according to claim 1, wherein
the amplifier is a differential amplifier outputting a pair of voltages having an offset when the optical signal is not received.

8. The circuit according to claim 1, wherein
the first compensator is biased to flow a current when the optical signal is not received.

9. The circuit according to claim 1, wherein
the first compensator is a clamp circuit.

10. The circuit according to claim 1, wherein
the first compensator holds the amplifier on an operating point being operable without saturation.

11. The circuit according to claim 2, wherein:
the first compensator and the second compensator hold the amplifier on the operating point being operable without saturation.

12. A photo-coupling type insulated circuit, comprising:
a light receiving circuit including:
a light receiving element configured to output an optical current by receiving an optical signal;
an amplifier configured to convert the optical current into a voltage and amplify the voltage; and
a first compensator connected to the amplifier and configured to suppress a variation in an opposite direction from a voltage variation of the amplifier when the optical current increases; and
a light emitting element configured to transmit the optical signal to the light receiving element.

13. The circuit according to claim 12, further comprising:
a second compensator connected to the amplifier and configured to suppress a variation in the direction of the voltage variation of the amplifier when the optical current increases.

14. The circuit according to claim 13, wherein
the amplifier includes a buffer amplifier set to a gain of unity, and
the second compensator is connected to an input of the buffer amplifier.

15. The circuit according to claim 14, wherein
the first compensator is connected to the input of the buffer amplifier.

16. The circuit according to claim 14, wherein
the first compensator is connected to an output of the buffer amplifier.

17. The circuit according to claim 12, further comprising
a reference element having electric characteristics with the light receiving element, shielded from the optical signal, and outputting a reference current.

18. The circuit according to claim 12, wherein
the first compensator is biased to flow a current when the optical signal is not received.

19. The circuit according to claim 12, wherein
the first compensator holds the amplifier on an operating point being operable without saturation.

20. The circuit according to claim 13, wherein:
the first compensator and the second compensator hold the amplifier on the operating point being operable without saturation.
